(19) United States
(12) Patent Application Publication
(10) Pub. No.: US 2024/0145539 A1
(43) Pub. Date: May 2, 2024

(54) STACKED TRANSISTORS HAVING MULTIPLE GATE DIELECTRICS AND MULTIPLE WORK FUNCTION METALS

(71) Applicant: INTERNATIONAL BUSINESS MACHINES CORPORATION, ARMONK, NY (US)

(72) Inventors: Julien Frougier, Albany, NY (US); Kangguo Cheng, Schenectady, NY (US); Ruilong Xie, Niskayuna, NY (US); Min Gyu Sung, Latham, NY (US); Chanro Park, Clifton Park, NY (US)

(21) Appl. No.: 18/051,958

(22) Filed: Nov. 2, 2022

(51) Int. Cl. H01L 29/06; H01L 27/092; H01L 29/423; H01L 29/775; H01L 29/786

(52) U.S. Cl. CPC H01L 29/0673; H01L 27/092; H01L 29/42392; H01L 29/775; H01L 29/78696

(57) ABSTRACT

A semiconductor structure including a stacked transistor structure comprising a top device stacked directly above a bottom device, and a bilayer gate dielectric layer separating the top device from the bottom device.

### BACKGROUND

The present invention generally relates to semiconductor structures, and more particularly to stacked transistor structures having multiple gate dielectric and multiple work function metals.

Integrated circuit (IC) chips are formed on semiconductor wafers at increasingly smaller scale. In current technology nodes, such as 7, 10 and 14 nanometer technologies, transistor devices are constructed as three-dimensional (3D) fin field effect transistor (FINFET) structures. However, chipmakers face a myriad of challenges at 5 nm, 3 nm and beyond. Currently, traditional chip scaling continues to slow as process complexities and costs escalate at each node.

A potential solution to this chip scaling problem is gate-all-around technology. One example of a complex gate-all-around technology is a stacked-FET where nFET and pFET nanowires/nanosheets are vertically stacked on top of each other.

### SUMMARY

According to an embodiment of the present invention, a semiconductor structure is provided. The semiconductor structure may include a stacked transistor structure comprising a top device stacked directly above a bottom device. and a bilayer gate dielectric layer separating the top device from the bottom device.

According to another embodiment of the present invention, a semiconductor structure is provided. The semiconductor structure may include a first stacked transistor structure comprising a top device stacked directly above a bottom device, a second stacked transistor structure adjacent to the first stacked transistor, the second stacked transistor comprising a top device stacked directly above a bottom device, and a bilayer gate dielectric layer separating the top devices from the bottom devices.

According to another embodiment of the present invention, a semiconductor structure is provided. The semiconductor structure may include a stacked nanosheet transistor array comprising a plurality of top devices stacked directly above a plurality of bottom devices, wherein each of the plurality of top devices comprises a different threshold voltage, wherein each of the plurality of bottom devices comprises a different threshold voltage, and a bilayer gate dielectric layer separating each of the plurality of top devices from each of the plurality of bottom devices.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2 and 3 are cross-sectional views of a semiconductor structure during an intermediate step of a method of fabricating a stacked transistor structure according to an exemplary embodiment;

FIGS. 4 and 5 are cross-sectional views of the semiconductor structure after forming shallow trench isolation regions according to an exemplary embodiment;

FIGS. 6 and 7 are cross-sectional views of the semiconductor structure after forming a sacrificial gate dielectric 116 and a first sacrificial gate structure according to an exemplary embodiment;

FIGS. 8 and 9 are cross-sectional views of the semiconductor structure after recessing the first sacrificial gate according to an exemplary embodiment;

FIGS. 10 and 11 are cross-sectional views of the semiconductor structure after forming a second sacrificial gate according to an exemplary embodiment;

FIGS. 12 and 13 are cross-sectional views of the semiconductor structure after patterning the first sacrificial gate and the second sacrificial gate according to an exemplary embodiment;

FIGS. 14 and 15 are a cross-sectional views of the semiconductor structure after selectively removing the second sacrificial nanosheets according to an exemplary embodiment;

FIGS. 16 and 17 are cross-sectional views of the semiconductor structure after forming a spacer material according to an exemplary embodiment;

FIGS. 18 and 19 are cross-sectional views of the semiconductor structure after removing portions of the nanosheet stacks and forming inner spacers according to an exemplary embodiment;

FIGS. 20 and 21 are cross-sectional views of the semiconductor structure after forming source drain regions and dielectric spacers according to an exemplary embodiment;

FIGS. 22 and 23 are cross-sectional views of the semiconductor structure after forming a dielectric layer according to an exemplary embodiment;

FIGS. 24 and 25 are cross-sectional views of the semiconductor structure after selectively removing the second sacrificial gate according to an exemplary embodiment;

FIGS. 26 and 27 are cross-sectional views of the semiconductor structure after selectively removing the first sacrificial nanosheets according to an exemplary embodiment;

FIGS. 28 and 29 are cross-sectional views of the semiconductor structure after forming a top gate structure including a first gate dielectric, a first work function metal layer, and a first gate metal according to an exemplary embodiment;

FIGS. 30 and 31 are cross-sectional views of the semiconductor structure after forming first source drain contacts and a self-aligned cap according to an exemplary embodiment;

FIGS. 32 and 33 are cross-sectional views of the semiconductor structure after forming a back-end-of-line and securing a carrier wafer according to an exemplary embodiment;

FIGS. 34 and 35 are cross-sectional views of the semiconductor structure after flipping the assembly and recessing the substrate according to an exemplary embodiment;

FIGS. 36 and 37 are cross-sectional views of the semiconductor structure after removing the substrate and replacing it with a dielectric fill according to an exemplary embodiment;

FIGS. 38 and 39 are cross-sectional views of the semiconductor structure after forming dielectric pillars to isolate adjacent devices according to an exemplary embodiment;

FIGS. 40 and 41 are cross-sectional views of the semiconductor structure after removing portions of the dielectric fill in preparation for forming gate structures in the bottom devices according to an exemplary embodiment;

FIGS. 42 and 43 are cross-sectional views of the semiconductor structure after etching exposed portions of the spacer material according to an exemplary embodiment;

FIGS. 44 and 45 are cross-sectional views of the semiconductor structure after selectively removing the first sacrificial nanosheets, the sacrificial gate dielectric, and the first sacrificial gate according to an exemplary embodiment;

FIGS. 46 and 47 are cross-sectional views of the semiconductor structure after forming a bottom gate structure including a second gate dielectric, a second work function metal layer, and a second gate metal according to an exemplary embodiment;

FIGS. 48 and 49 are cross-sectional views of the semiconductor structure after forming gate contact structures 158, or CB contacts, according to an exemplary embodiment; and

FIGS. 50 and 51 are cross-sectional views of a semiconductor structure during an intermediate step of a method of fabricating a stacked transistor structure according to an alternative embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, or stacked transistors, have known advantages over conventional transistor structures in terms of density, performance, power consumption, and integration. However, fabricating stacked transistor devices with different gate materials and workfunction metals presents unique challenges. More specifically, for example, current fabrication techniques do not allow for individual selection of different gate materials and workfunction metals to enable individual NFET and PFET devices in a stacked architecture.

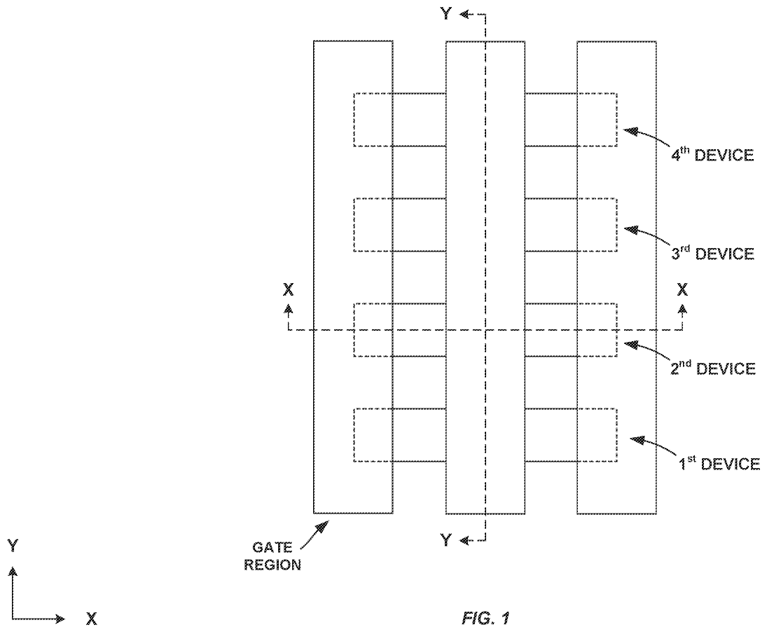

The present invention generally relates to semiconductor structures, and more particularly to stacked transistor structures having multiple gate dielectric and multiple work function metals. More specifically, the stacked transistor structures and associated method disclosed herein enable a novel solution for providing stacked transistors having different gate materials and work function metals. Exemplary embodiments of stacked transistors having different gate materials and work function metals are described in detail below by referring to the accompanying drawings in FIGS. 1 to 49. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows a first fin/stack, a second fin/stack, a third fin/stack, a fourth fin/stack, and a gate region situated perpendicular to the fins. FIGS. 1-49 represent cross section views oriented as indicated in FIG. 1.

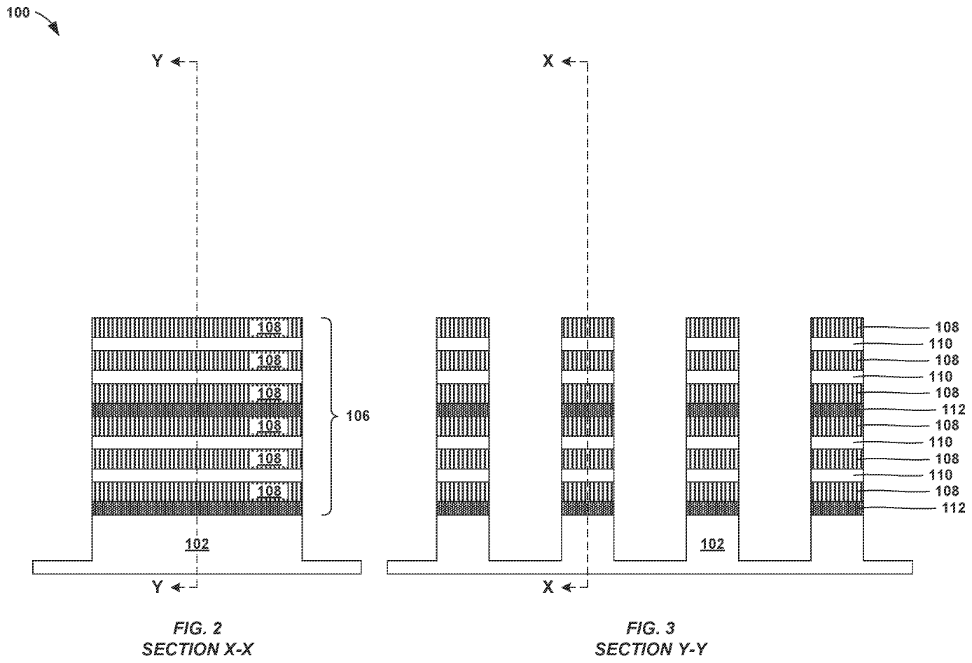

Referring now to FIGS. 2 and 3, a structure 100 is shown during an intermediate step of a method of fabricating a stacked transistor structure according to an embodiment of the invention. FIG. 2 depicts a cross-sectional view of the structure 100 shown in FIG. 3 taken along line X-X, and FIG. 3 depicts a cross-sectional view of the structure 100 shown in FIG. 2 taken along line Y-Y.

The structure 100 illustrated in FIGS. 2 and 3 includes nanosheet stacks 106, or fins, formed from an alternating series of first silicon germanium (SiGe) sacrificial nanosheets 108 (hereinafter “first sacrificial nanosheets 108”), silicon (Si) channel nanosheets 110 (hereinafter “channel nanosheets 110”), and second silicon germanium (SiGe) sacrificial nanosheets 112 (hereinafter “second sacrificial nanosheets 112”), as illustrated. The nanosheet stacks 106 are formed on a silicon substrate 102. Although only a limited number of nanosheet stacks 106 and nanosheet layers are shown, one or more additional nanosheet stacks and/or nanosheets can optionally be epitaxially grown in an alternating fashion, and the properties of any additional nanosheets are the same as the corresponding nanosheets described herein.

According to embodiments of the present disclosure, the first sacrificial nanosheets 108 have a different germanium concentration than the second sacrificial nanosheets 112. In at least one embodiment, the second sacrificial nanosheets 112 have a higher germanium concentration than the first sacrificial nanosheets 108. More specifically, for example, the second sacrificial nanosheets 112 may have a germanium concentration ranging from about 45 to about 70 percent, while the first sacrificial nanosheets 108 may have a germanium concentration ranging from about 15 to about 40 percent. In all cases, the different germanium concentrations are designed to allow for each of the first sacrificial nanosheets 108 and the second sacrificial nanosheets 112 to be etched selective to one another. As such, other germanium concentrations are explicitly contemplated.

In one or more embodiments, the nanosheet stacks 106 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, in at least one embodiment, each nanosheet stack 106 includes channel nanosheets 110 which are doped, undoped or some combination thereof.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a 11001 orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

Known processing techniques have been applied to the alternating layers to form the nanosheet stack 106 shown in FIGS. 2 and 3. For example, the known processing techniques can include the formation of hard masks (not shown) over the topmost layer of the nanosheet stack 106. The hard masks can be formed by first depositing the hard mask material (for example silicon nitride) onto the topmost layer of the nanosheet stack 106 using, for example, chemical vapor deposition (CVD), plasma enhanced CVD (PECVD) or any suitable technique for dielectric deposition that does not induce a physical or chemical change to the topmost layer of the nanosheet stack 106. According to an exemplary embodiment, the hard mask material is deposited onto the first sacrificial nanosheets 108 at the top of the nanosheet stack 106 and then patterned into a plurality of the individual hard masks. Patterning the hard mask is commensurate with a desired footprint and location of the nanosheet stacks 106 shown in FIG. 3, which will subsequently be used to form the channel regions of semiconductor devices disclosed herein. According to an exemplary embodiment, RIE is used to transfer the hard mask pattern into the alternating layers to form the nanosheet stacks 106, and into the substrate 102, as shown.

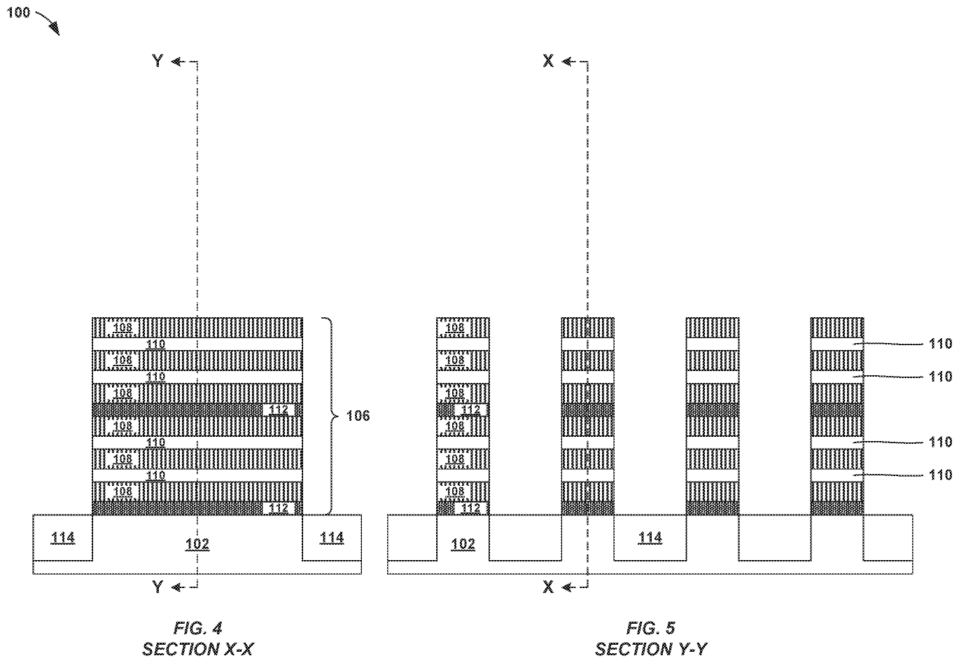

Referring now to FIGS. 4 and 5, a structure 100 is shown after forming shallow trench isolation regions 114 (hereinafter “STI regions 114”) according to an embodiment of the invention. FIG. 4 depicts a cross-sectional view of the structure 100 shown in FIG. 5 taken along line X-X, and FIG. 5 depicts a cross-sectional view of the structure 100 shown in FIG. 4 taken along line Y-Y.

The STI regions 114 are formed at the bottom of trenches in the substrate 102 formed during patterning of the nanosheet stacks 106. Specifically, a dielectric material is deposited at the bottom of trenches in the substrate 102 to isolate adjacent devices from one another according to known techniques. The STI regions 114 may be formed from any appropriate dielectric material including, for example, silicon oxide (SiOₓ) or silicon nitride (SiₓN_{y}).

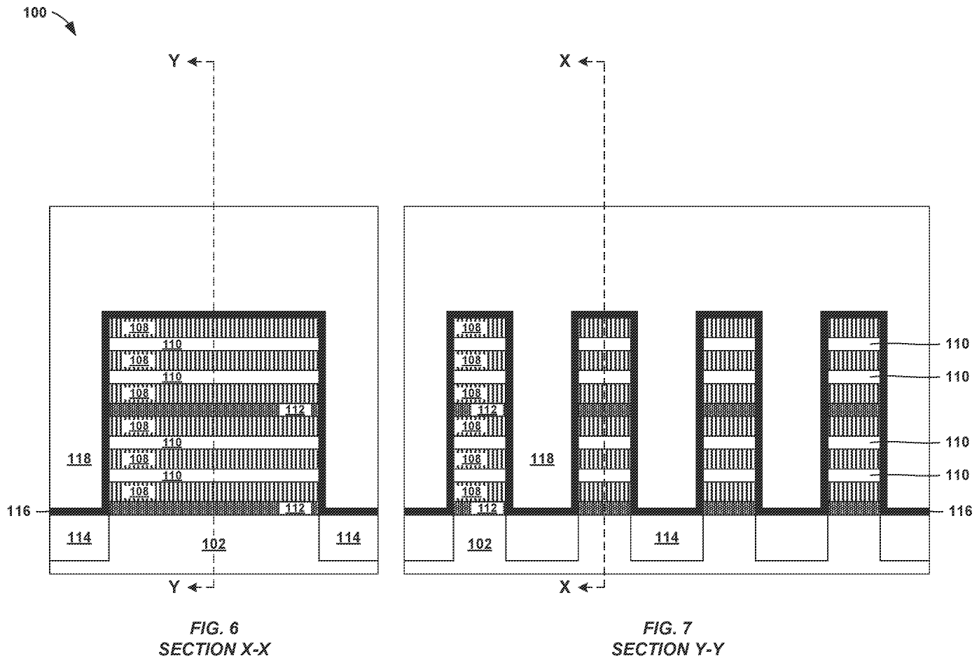

Referring now to FIGS. 6 and 7, a structure 100 is shown after forming a sacrificial gate dielectric 116 and a first sacrificial gate 118 according to an embodiment of the invention. FIG. 6 depicts a cross-sectional view of the structure 100 shown in FIG. 7 taken along line X-X, and FIG. 7 depicts a cross-sectional view of the structure 100 shown in FIG. 6 taken along line Y-Y.

The sacrificial gate dielectric 116 is deposited directly on exposed surfaces of the structure 100 according to known techniques. Specifically, for example, a relatively thin layer of silicon oxide (SiO2) is first conformally deposited over and around the nanosheet stacks 106, as illustrated.

The first sacrificial gate 118 is blanket deposited over and around the nanosheet stacks 106 according to known techniques. Specifically, for example, a relatively thick layer of boron doped silicon is blanket deposited directly on the sacrificial gate dielectric 116, as illustrated. In this manner, both the sacrificial gate dielectric 116 and the first sacrificial gate 118 completely cover the nanosheet stacks 106, as illustrated.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

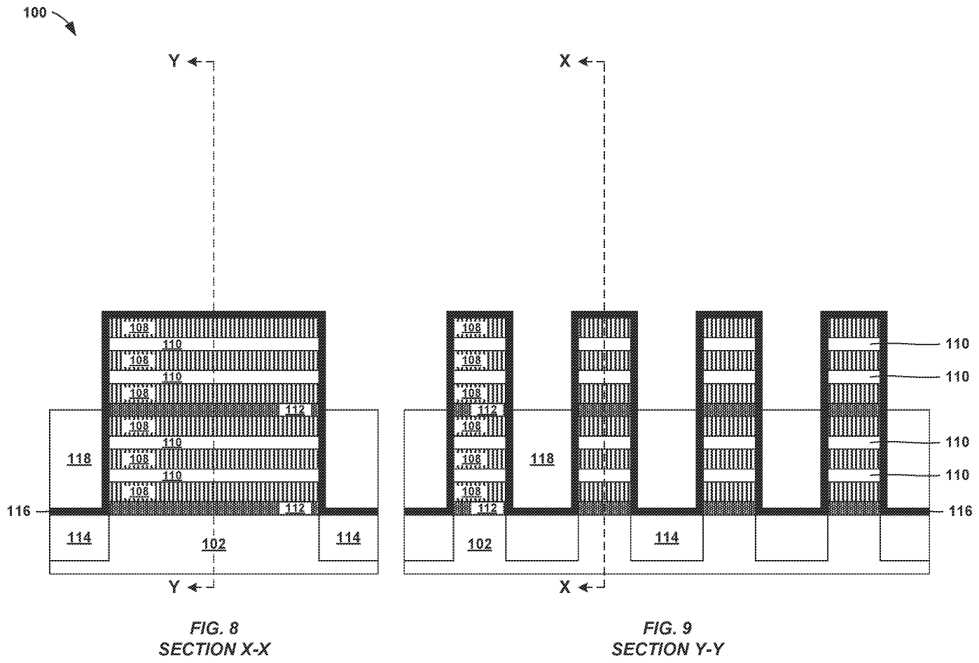

Referring now to FIGS. 8 and 9, a structure 100 is shown after recessing the first sacrificial gate 118 according to an embodiment of the invention. FIG. 8 depicts a cross-sectional view of the structure 100 shown in FIG. 9 taken along line X-X, and FIG. 9 depicts a cross-sectional view of the structure 100 shown in FIG. 8 taken along line Y-Y.

The first sacrificial gate 118 may be recessed using any suitable method, such as a wet etch, a dry etch, or a combination of sequential wet and/or dry etches. In an embodiment, the first sacrificial gate 118 is recessed using an anisotropic etch such as, for example, reactive ion etching. Etching is designed to expose the first sacrificial nanosheets 108 and the channel nanosheets 110 above the second sacrificial nanosheets 112. In all cases, etching stops before exposing the first sacrificial nanosheets 108 and the channel nanosheets 110 below the second sacrificial nanosheets 112 positioned in the center of the stack, as illustrated. It is critical that the first sacrificial nanosheets 108 and the channel nanosheets 110 below the second sacrificial nanosheets 112 remain covered or protected by the first sacrificial gate 118 to enable subsequent processing sequences described below. As such, the uppermost surface or the first sacrificial gate 118 after recessing will be above a lowermost surface of the second sacrificial nanosheets 112 and below the uppermost surface of the second sacrificial nanosheets 112, as illustrated. Finally, as this stage, the first sacrificial gate 118 is recessed selective to the sacrificial gate sacrificial gate dielectric 116.

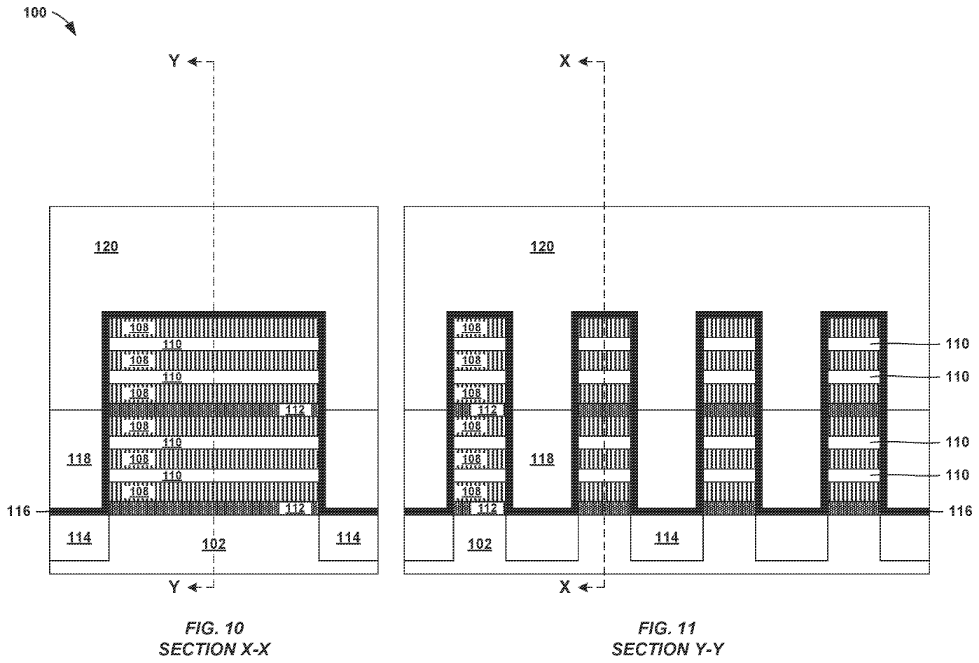

Referring now to FIGS. 10 and 11, a structure 100 is shown after forming a second sacrificial gate 120 according to an embodiment of the invention. FIG. 10 depicts a cross-sectional view of the structure 100 shown in FIG. 11 taken along line X-X, and FIG. 11 depicts a cross-sectional view of the structure 100 shown in FIG. 10 taken along line Y-Y.

The second sacrificial gate 120 is blanket deposited over and around the nanosheet stacks 106 according to known techniques. Specifically, for example, a relatively thick layer of amorphous silicon (a-Si) is blanket deposited directly on the sacrificial gate dielectric 116 and the first sacrificial gate 118, as illustrated. In this manner, the second sacrificial gate 120 covers a top half of the nanosheet stacks 106, as illustrated.

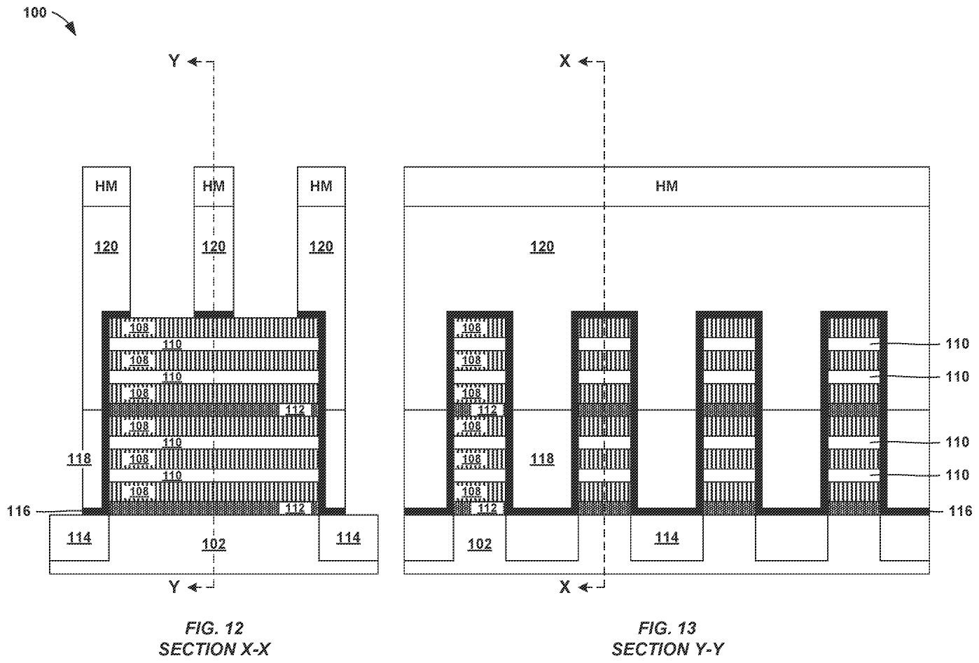

Referring now to FIGS. 12 and 13, a structure 100 is shown after patterning the first sacrificial gate 118 and the second sacrificial gate 120 according to an embodiment of the invention. FIG. 12 depicts a cross-sectional view of the structure 100 shown in FIG. 13 taken along line X-X, and FIG. 13 depicts a cross-sectional view of the structure 100 shown in FIG. 12 taken along line Y-Y.

First, a gate cut mask (hard mask or HM) is formed over the structure 100. The hard mask defines gate regions of individual devices. According to an exemplary embodiment, the hard mask material is deposited onto the second sacrificial gate 120 and then patterned into a plurality of individual hard masks. Next, the pattern created by the individual hard masks is transferred into the second sacrificial gate 120 and the first sacrificial gate 118. Specifically, portions of the first sacrificial gate 118 and the second sacrificial gate 120 are etched or removed selective to the gate dielectric 116, as illustrated. The portions of the second sacrificial gate 120 and the first sacrificial gate 118 can be removed using a silicon RIE process. Finally, a clean process is used to remove exposed portions of the gate dielectric 116, as illustrated.

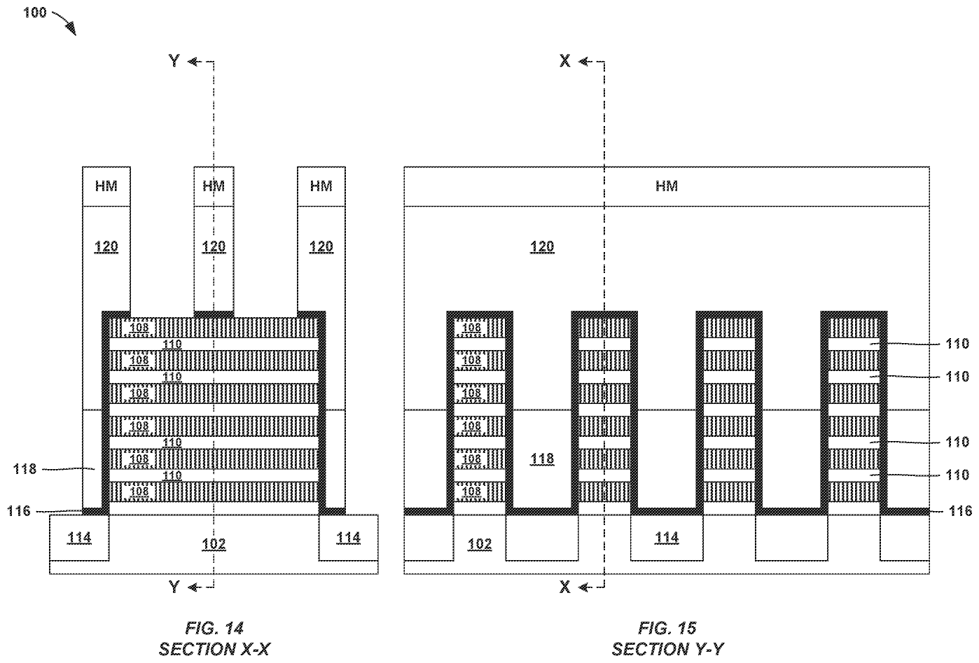

Referring now to FIGS. 14 and 15, a structure 100 is shown after selectively removing the second sacrificial nanosheets 112 according to an embodiment of the invention. FIG. 14 depicts a cross-sectional view of the structure 100 shown in FIG. 15 taken along line X-X, and FIG. 15 depicts a cross-sectional view of the structure 100 shown in FIG. 14 taken along line Y-Y.

More specifically, the second sacrificial nanosheets 112 are etched and removed selective to the first sacrificial nanosheets 108 or the channel nanosheets 110 according to known techniques. Doing so is made possible by the different concentrations of germanium. In this case, the layers with the relatively higher germanium concentration are removed selective to layers with the relatively lower germanium concentrations.

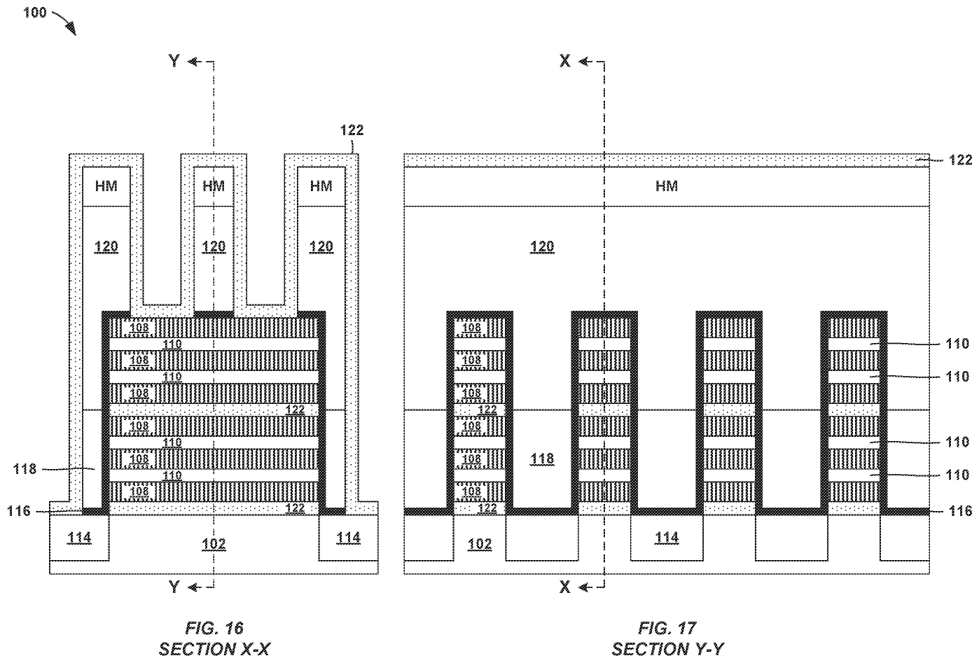

Referring now to FIGS. 16 and 17, a structure 100 is shown after forming a spacer material 122 according to an embodiment of the invention. FIG. 16 depicts a cross-sectional view of the structure 100 shown in FIG. 17 taken along line X-X, and FIG. 17 depicts a cross-sectional view of the structure 100 shown in FIG. 16 taken along line Y-Y.

The spacer material 122 is deposited directly on exposed surfaces of the structure 100 according to known techniques. Specifically, for example, a relatively thin layer of silicon nitride is conformally deposited as illustrated. In some embodiments, for example, the spacer material 122 may be composed of SiN, SiBCN, SiOCN, SiOC, or any other combination of low-k materials. According to embodiments of the present disclosure, the spacer material 122 substantially fills the space created by removing the second sacrificial nanosheets 112, and functions to isolate top devices from bottom devices. Further, according to embodiments of the present disclosure, the spacer material 122 substantially covers vertical sidewalls of the first sacrificial gate 118 and the second sacrificial gate 120, and functions to isolate subsequently formed gate structures, as described in more detail below.

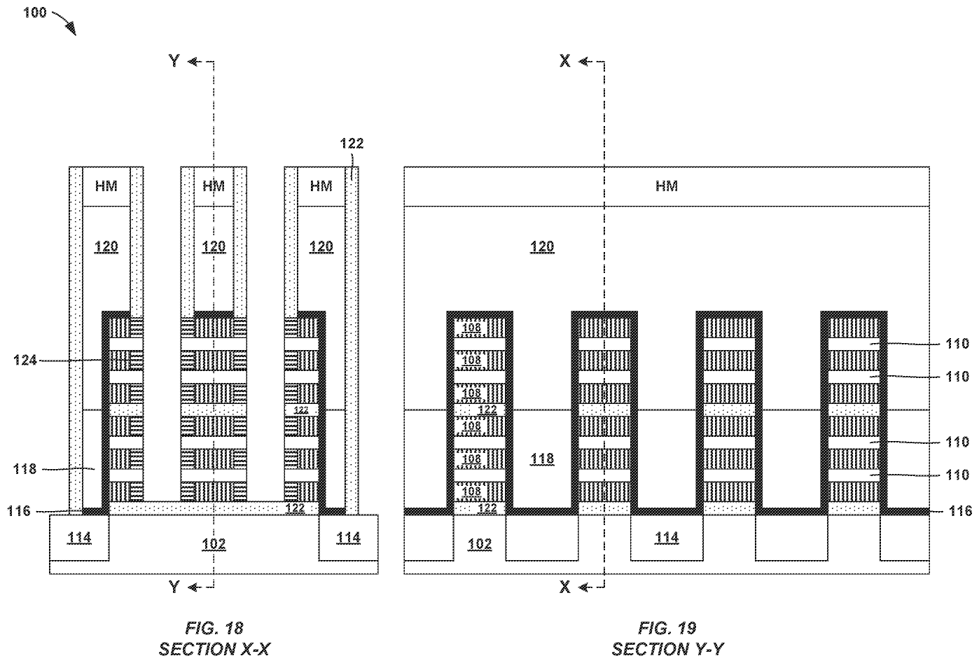

Referring now to FIGS. 18 and 19, a structure 100 is shown after removing portions of the nanosheet stacks 106 and forming inner spacers 124 according to an embodiment of the invention. FIG. 18 depicts a cross-sectional view of the structure 100 shown in FIG. 19 taken along line X-X, and FIG. 19 depicts a cross-sectional view of the structure 100 shown in FIG. 18 taken along line Y-Y.

First, in at least an embodiment, portions of the spacer material 122 are selectively removed or etched from horizontal surfaces according to known techniques. Doing so will generally expose the nanosheet stacks 106.

Next, portions of the nanosheet stacks 106 are etched and removed from between the sacrificial gates 118, 120 according to known techniques. Specifically, the pattern created by the individual hard masks (HM) and gate spacers 122 is transferred into the sacrificial gate dielectric 116 and the nanosheet stacks 106. In doing so, portions of the sacrificial gate dielectric 116, the first sacrificial nanosheets 108, and the channel nanosheets 110, are removed selective to the spacer material 122, as illustrated.

In an embodiment, portions of the nanosheet stacks 106 are removed using an anisotropic etch such as, for example, reactive ion etching. Doing so may require a series of multiple etching steps using different etch chemistries as is well known in the art. Etching is designed to define source drain regions and expose ends of individual nanosheet layers. In all cases, etching stops before exposing the substrate 102.

After patterning the source drain regions, the first sacrificial nanosheets 108 are laterally recessed to make room for the inner spacers 124. In one or more embodiments, the first sacrificial nanosheets 108 are laterally recessed using a hydrogen chloride (HCL) gas isotropic etch process, which etches silicon germanium without attacking silicon. In other embodiments, the first sacrificial nanosheets 108 are laterally recessed using a ClF3 etch process. Cavities (not shown) are formed by spaces that were occupied by the removed portions of the first sacrificial nanosheets 108.

The inner spacers 124 are formed by first conformally depositing a spacer material over the structure 100 to fill the cavities created by laterally recessing the first sacrificial nanosheets 108. The conformal spacer material is then isotropically etched to remove all portions except those remaining in the cavities and forming the inner spacers 124. In one or more embodiments, the inner spacers 124 are made from a nitride containing material, for example silicon nitride (SiN). Although inner spacers 124 shown in FIGS. 18 and 19 are formed from a nitride containing material, they can be formed from any material for which subsequent device fabrication operations are not very selective. Selectivity, as used in the present description, refers to the tendency of a process operation to impact a particular material. One example of low selectivity is a relatively slow etch rate. One example of a higher or greater selectivity is a relatively faster etch rate. For the described embodiments, a material for the inner spacers 124 can be selected based on a selectivity of subsequent device fabrication operations for the selected material being below a predetermined threshold.

The inner spacers 124 are positioned such that subsequent etching processes used to remove the first sacrificial nanosheets 108 during device fabrication do not also attack subsequently formed source drain regions.

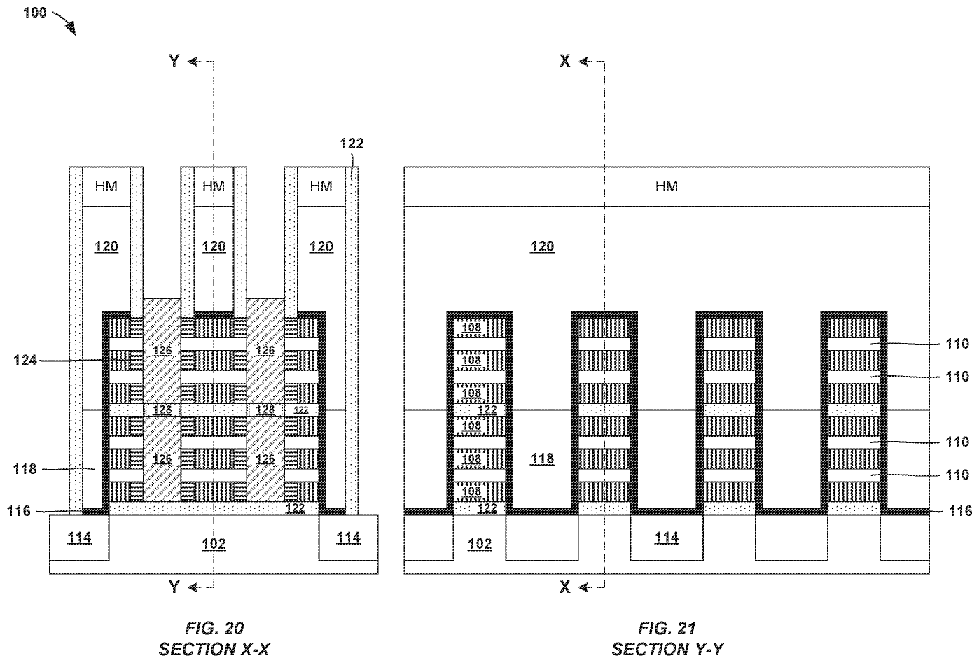

Referring now to FIGS. 20 and 21, a structure 100 is shown after forming source drain regions 126 and dielectric spacers 128 according to an embodiment of the invention. FIG. 20 depicts a cross-sectional view of the structure 100 shown in FIG. 21 taken along line X-X, and FIG. 21 depicts a cross-sectional view of the structure 100 shown in FIG. 20 taken along line Y-Y.

The source drain regions 126 are formed using an epitaxial layer growth process on the exposed ends of the channel nanosheets 110 according to known techniques. Typically, in-situ doping is used to dope the source drain regions 126, thereby creating the necessary junctions of the semiconductor device. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a P-type piece of silicon, rich in holes, and an N-type piece of silicon, rich in electrons. N-type and P-type devices are formed by using different types of dopants to select regions of the device to form the necessary junction(s). For example, N-type devices can be formed by doping with arsenic (As) or phosphorous (P), and p-type devices can be formed by doping with implanting boron (B).

The dielectric spacers 128 are formed by depositing a dielectric material over the structure 100 according to known techniques. The dielectric spacers 128 are formed between the source drain regions 126 of lower and upper devices, as illustrated. In an embodiment, the dielectric spacers 128 are composed of any suitable dielectric material, for example Si₃N₄, SiBCN, SiNC, SiN, SiCO, SiO₂, SiNOC, etc. In all cases, the dielectric spacers 128 are substantially aligned with the spacer material 122 which also separates lower devices from upper devices, as illustrated.

In stacked configurations, such as the embodiments described herein, a bottom source drain region (126) is formed first, followed by the dielectric spacer 128, and then followed by a top source drain region (126). As such, the top and bottom source drain regions (126) can be separately doped with different dopants. Therefore, for example, the bottom source drain region can be N-type and the top source drain can be P-type, or vice versa. Furthermore, for example, the top source drain region and the bottom source drain region can both be N-type or P-type.

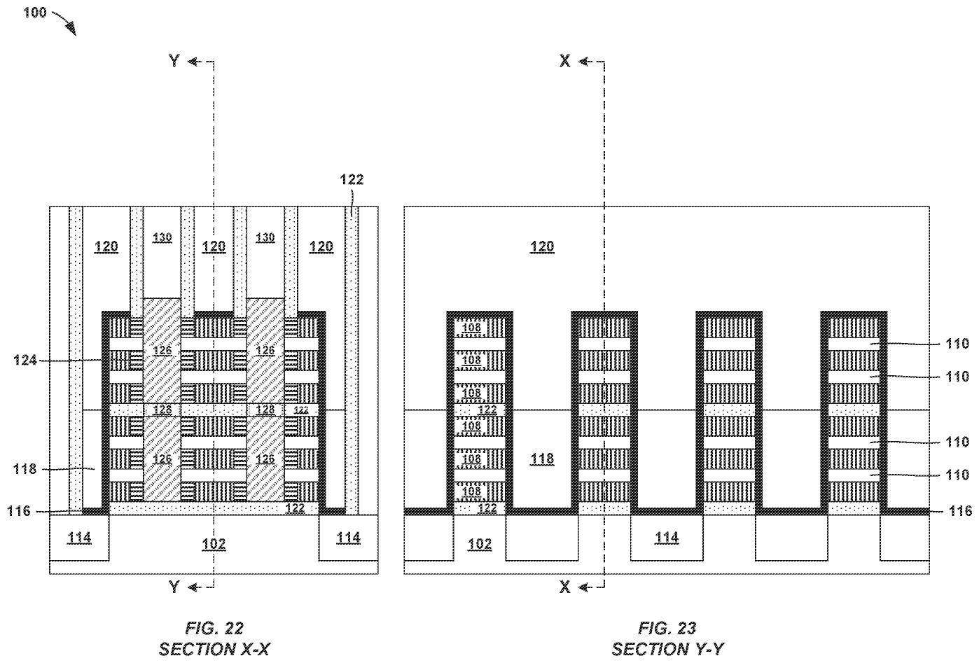

Referring now to FIGS. 22 and 23, a structure 100 is shown after forming a dielectric layer 130 according to an embodiment of the invention. FIG. 22 depicts a cross-sectional view of the structure 100 shown in FIG. 23 taken along line X-X, and FIG. 23 depicts a cross-sectional view of the structure 100 shown in FIG. 22 taken along line Y-Y.

The dielectric layer 130 is formed by blanket depositing an interlayer dielectric material over the structure 100 according to known techniques. Specifically, the dielectric layer 130 is formed on the source drain regions 126 and substantially fills the remaining space between the spacer material 122, as illustrated. After, the dielectric layer 130 can be polished using known techniques until a topmost surface of the dielectric layer 130 is flush, or substantially flush, with topmost surfaces of the second sacrificial gate 120 and the spacer material 122, as illustrated.

The dielectric layer 130 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. In another embodiment, a self-planarizing material such as a spin-on glass (SOG) or a spin-on low-k dielectric material such as SiLK™ can be used as the dielectric layer 130. Using a self-planarizing dielectric material as the dielectric layer 130 can avoid the need to perform a subsequent planarizing step.

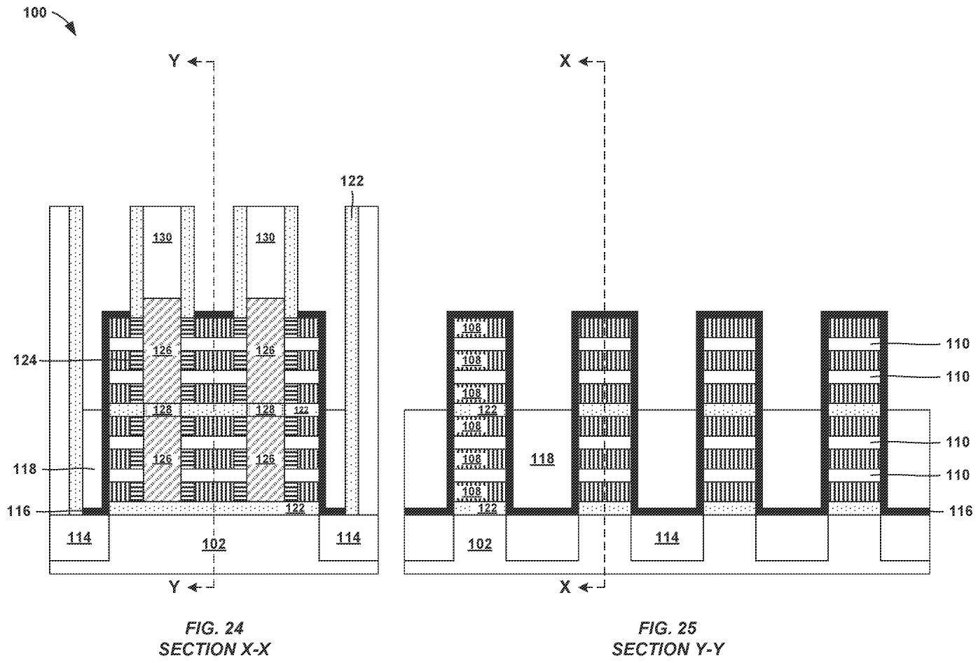

Referring now to FIGS. 24 and 25, a structure 100 is shown after selectively removing the second sacrificial gate 120 according to an embodiment of the invention. FIG. 24 depicts a cross-sectional view of the structure 100 shown in FIG. 25 taken along line X-X, and FIG. 25 depicts a cross-sectional view of the structure 100 shown in FIG. 24 taken along line Y-Y.

More specifically, the second sacrificial gate 120 is etched and removed selective to the spacer material 122, the sacrificial gate dielectric 116, and the first sacrificial gate 118 according to known techniques.

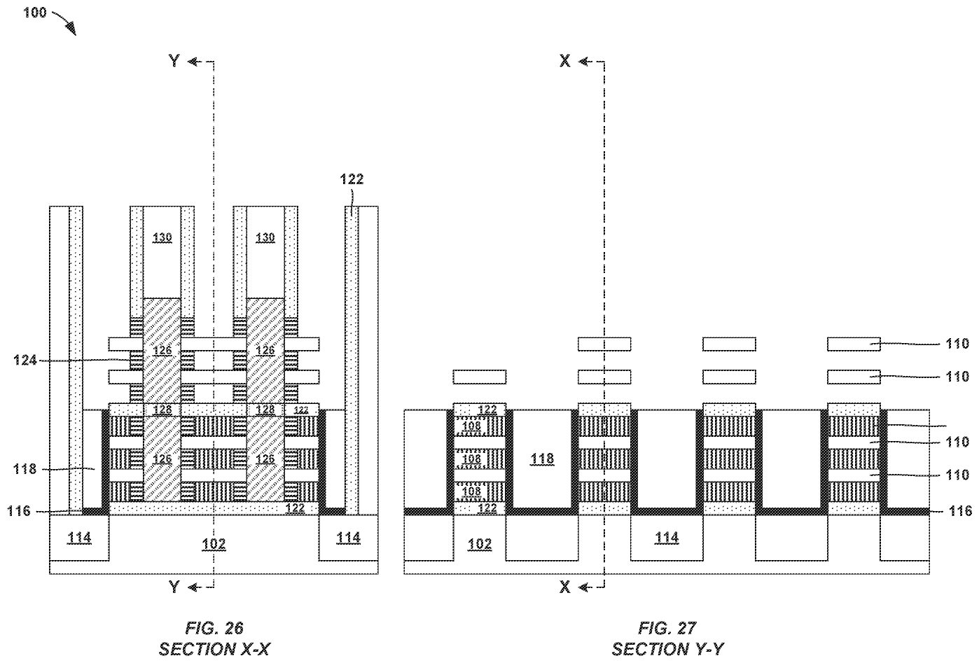

Referring now to FIGS. 26 and 27, a structure 100 is shown after selectively removing the first sacrificial nanosheets 108 according to an embodiment of the invention. FIG. 26 depicts a cross-sectional view of the structure 100 shown in FIG. 27 taken along line X-X, and FIG. 27 depicts a cross-sectional view of the structure 100 shown in FIG. 26 taken along line Y-Y.

First, the sacrificial gate dielectric 116 must be etched back or recessed to expose portions of the nanosheet stacks 106, as illustrated. Next, the first sacrificial nanosheets 108 are etched and removed selective to the channel nanosheets 110 and the spacer material 122 according to known techniques. Doing so is made possible by the different concentrations of germanium. In this case, the layers with germanium are removed selective to layers without germanium. It is noted the first sacrificial nanosheets 108 are removed from top devices only. That is, the first sacrificial nanosheets 108 are removed only above the spacer material 122, as illustrated. Some of the first sacrificial nanosheets 108 remain below the spacer material 122 and covered or protected by the first sacrificial gate 118.

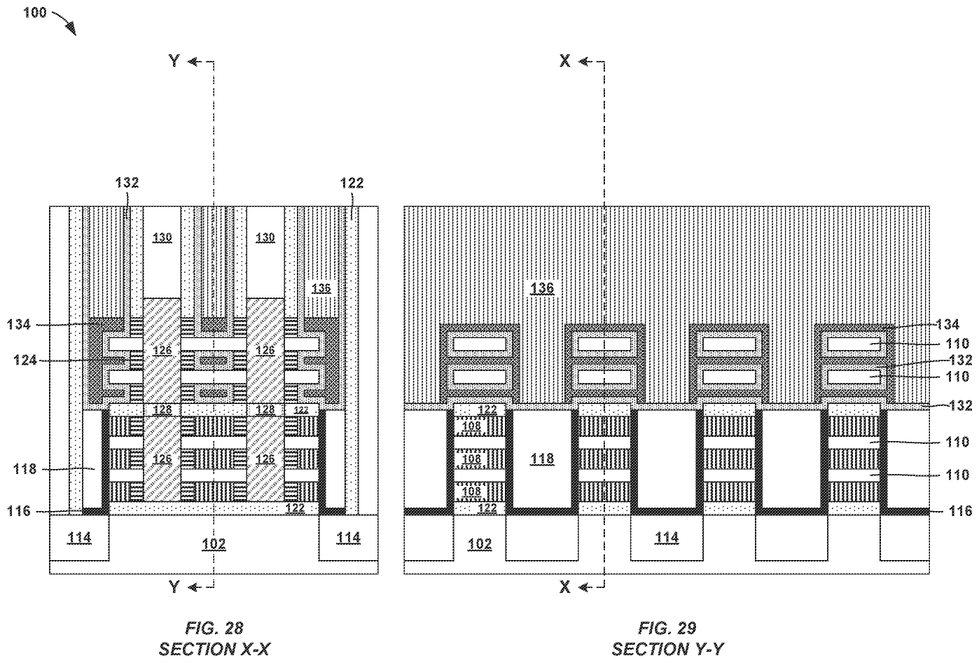

Referring now to FIGS. 28 and 29, a structure 100 is shown after forming a top gate structure including a first gate dielectric 132, a first work function metal layer 134, and a first gate metal 136 according to an embodiment of the invention. FIG. 28 depicts a cross-sectional view of the structure 100 shown in FIG. 29 taken along line X-X, and FIG. 29 depicts a cross-sectional view of the structure 100 shown in FIG. 28 taken along line Y-Y.

First, the first gate dielectric 132 is conformally deposited directly on exposed surfaces of the structure 100 within the openings and spaces left by removing the second sacrificial gate 120 and the first sacrificial nanosheets 108 according to known techniques. For example, the first gate dielectric 132 is conformally deposited on exposed surfaces of the channel nanosheets 110 and the inner spacers 124, as best illustrated in FIG. 29. Additionally, the first gate dielectric 132 is conformally deposited on exposed surfaces of the sacrificial gate dielectric 116, the first sacrificial gate 118, and the spacer material 122, as best illustrated in FIG. 28.

The first gate dielectric 132 is composed of any known gate dielectric materials, for example, oxide, nitride, and/or oxynitride. In an example, the first gate dielectric 132 can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNx, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the first gate dielectric 132. In at least one embodiment, the first gate dielectric 132 is composed of hafnium oxide.

Next, the first work function metal layer 134 is conformally deposited on the first gate dielectric 132 formed within the gate cavities according to known techniques. In at least one embodiment, the first work function metal layer 134 is made of the same conductive material across the entire structure. In at least another embodiment, the first work function metal layer 134 is made from different conductive materials in each of the four devices illustrated in FIG. 29. In doing so, the different conductive materials would be deposited successively according to the design parameters and desired operation characteristics.

The first work function metal layer 134 can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium cabon (TiC), titanium aluminum (TiAl), titanium aluminum carbon (TiAlC), or multilayered combinations thereof. In some embodiments, the first work function metal layer 134 can include an nFET gate metal. In other embodiments, the first work function metal layer 134 can include a pFET gate metal. When multiple gate cavities are formed, as illustrated herein, embodiments of the present invention explicitly contemplate forming an nFET in at least one of the gate cavities and a pFET in at least another one of the gate cavities.

Finally, the first gate metal 136, or contact metal, is deposited directly on the first work function metal layer 134 and fills the gate cavities. The first gate metal 136 may include any suitable conductive material, such as, for example, copper, ruthenium, aluminum, tungsten, cobalt, or alloys thereof. After, excess conductive material can be polished using known techniques until a topmost surface of the first gate metal 136 is flush, or substantially flush, with topmost surfaces of the bottom dielectric layer 130.

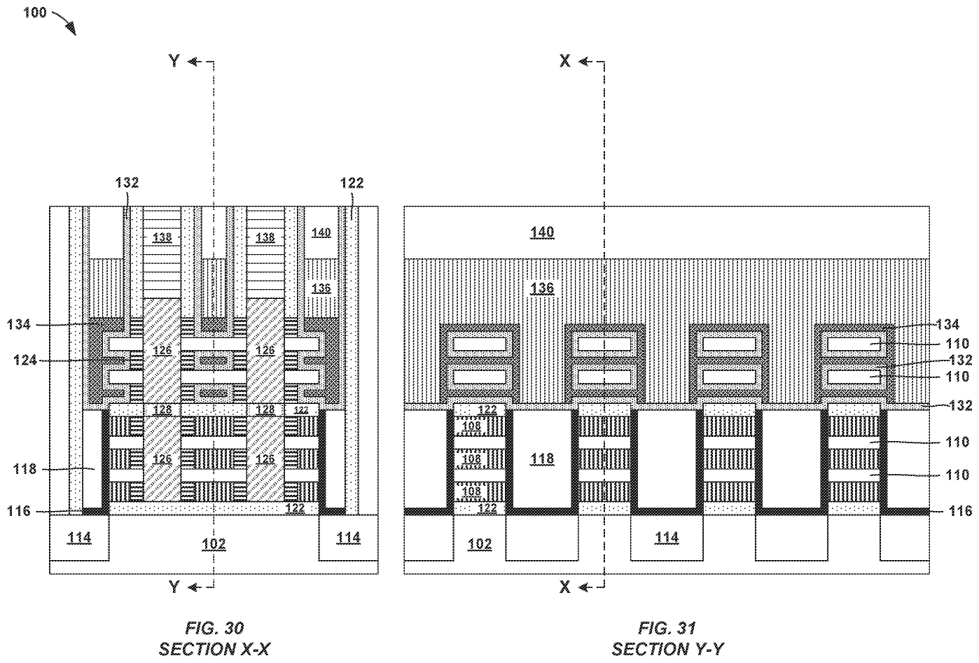

Referring now to FIGS. 30 and 31, a structure 100 is shown after forming first source drain contacts 138 and a self-aligned cap 140 according to an embodiment of the invention. FIG. 30 depicts a cross-sectional view of the structure 100 shown in FIG. 31 taken along line X-X, and FIG. 31 depicts a cross-sectional view of the structure 100 shown in FIG. 30 taken along line Y-Y.

First, the first gate metal 136 is recessed and the self-aligned cap 140 are formed in the recesses according to known techniques. More specifically, the self-aligned cap 140 is deposited directly on top of the first gate metal 136 and fills the openings and spaces left by recessing the first gate metal 136. In most cases, the self-aligned cap 140 will also be deposited on uppermost surfaces of the structure 100 at large but subsequently removed or polished by known techniques. More specifically, after polishing a topmost surface of the self-aligned cap 140 is flush, or substantially flush, with topmost surfaces of the self-aligned cap 140 is flush, or substantially flush, with topmost surfaces of the first source drain contacts 138, as shown. The self-aligned cap 140 can be composed of any known dielectric materials which are capable of electrically isolating the first gate metal 136.

Next, portions of the dielectric layer 130 are removed to expose the source drain regions 126. Next, the openings are filled with a conductive material to form the first source drain contacts 138 according to known techniques. The first source drain contacts 138 may include any suitable conductive material, such as, for example, copper, ruthenium, aluminum, tungsten, cobalt, or alloys thereof. In some embodiments, a metal silicide is formed at the bottom of the contact trenches prior to filling them with the conductive material. After, excess conductive material can be polished using known techniques until a topmost surface of the first source drain contacts 138 are flush, or substantially flush, with topmost surfaces of the spacer material 122, the first gate dielectric 132, and the first gate metal 136. As such, the first source drain contacts 138 are self-aligned to the spacer material 122, and thus may be referred to as self-aligned contact structures. It is noted the first source drain contacts 138 directly contact only the source drawing regions 126 above the dielectric spacers 128, or otherwise the source drain regions for the top devices.

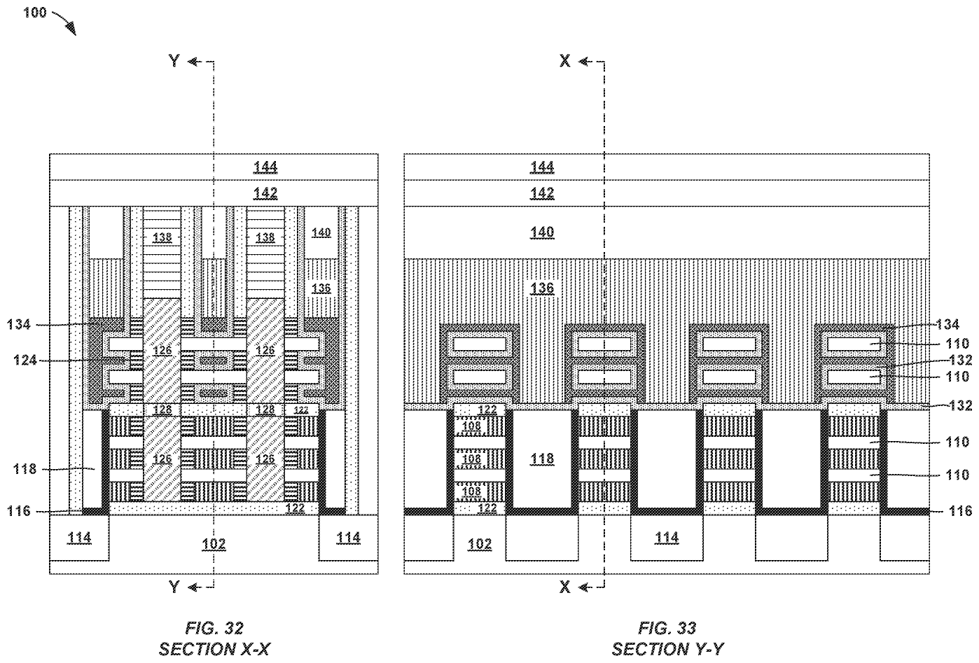

Referring now to FIGS. 32 and 33, a structure 100 is shown after forming a middle-of-line and back-end-of-line 142 (hereinafter MOL/BEOL 142) and securing a carrier wafer 144 according to an embodiment of the invention. FIG. 32 depicts a cross-sectional view of the structure 100 shown in FIG. 33 taken along line X-X, and FIG. 33 depicts a cross-sectional view of the structure 100 shown in FIG. 32 taken along line Y-Y.

After forming the first source drain contacts 138, the MOL/BEOL 142 is subsequently formed according to known techniques. Next, the carrier wafer 144 is attached, or removably secured, to the MOL/BEOL 142. In general, and not depicted, the carrier wafer 144 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 144 according to known techniques.

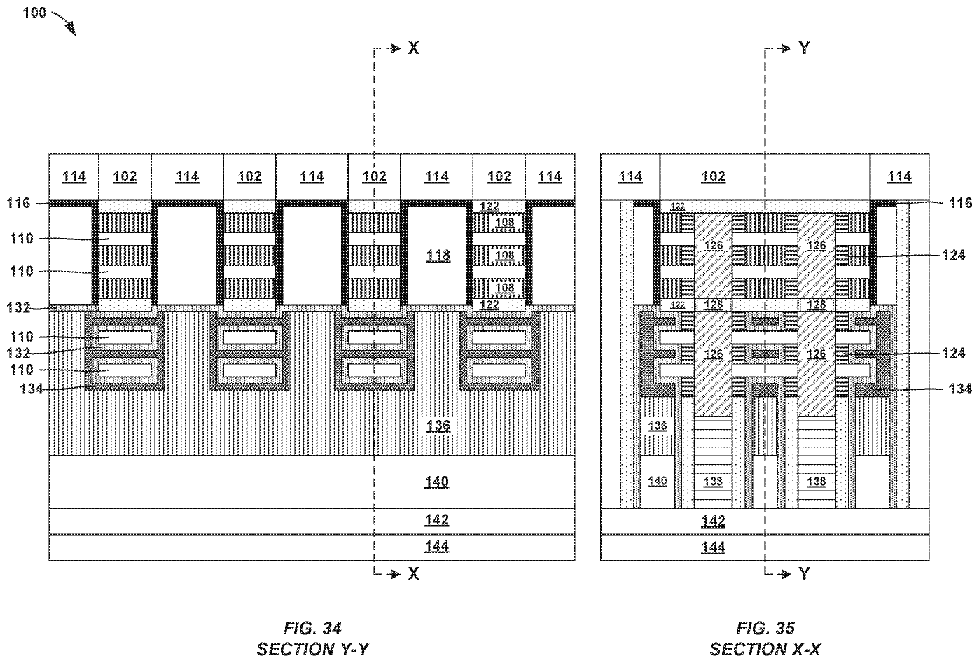

Referring now to FIGS. 34 and 35, a structure 100 is shown after flipping the assembly and recessing the substrate 102 according to an embodiment of the invention. FIG. 34 depicts a cross-sectional view of the structure 100 shown in FIG. 35 taken along line X-X, and FIG. 35 depicts a cross-sectional view of the structure 100 shown in FIG. 34 taken along line Y-Y.

First, the structure 100 is flipped 180 degrees to prepare for backside processing. In general, backside processing includes fabrication or processing of the structure 100 opposite the active device and wiring layers. Next, the substrate 102 is recessed to expose the STI regions 114 according to known techniques, as shown.

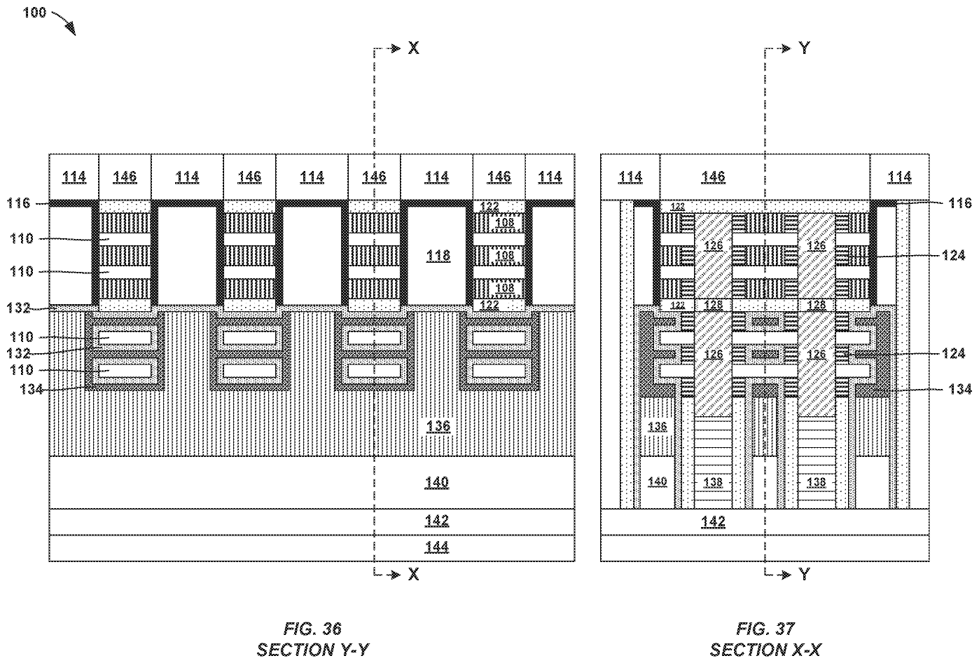

Referring now to FIGS. 36 and 37, a structure 100 is shown after removing the substrate 102 and replacing it with a dielectric fill 146 according to an embodiment of the invention. FIG. 36 depicts a cross-sectional view of the structure 100 shown in FIG. 37 taken along line X-X, and FIG. 37 depicts a cross-sectional view of the structure 100 shown in FIG. 36 taken along line Y-Y.

First, remaining portions of the substrate 102 are removed selective to the STI regions 114 and exposing the spacer material 122. Next, the dielectric fill 146 is formed by depositing an interlayer dielectric material over the structure 100 according to known techniques. The dielectric fill 146 is formed on the spacer material 122 and substantially filling the space between adjacent STI regions 114. After, the dielectric fill 146 can be polished using known techniques until a topmost surface of the dielectric fill 146 is flush, or substantially flush, with topmost surfaces of the STI regions 114, as illustrated.

The dielectric fill 146 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the dielectric fill 146. Using a self-planarizing dielectric material as the dielectric fill 146 can avoid the need to perform a subsequent planarizing step.

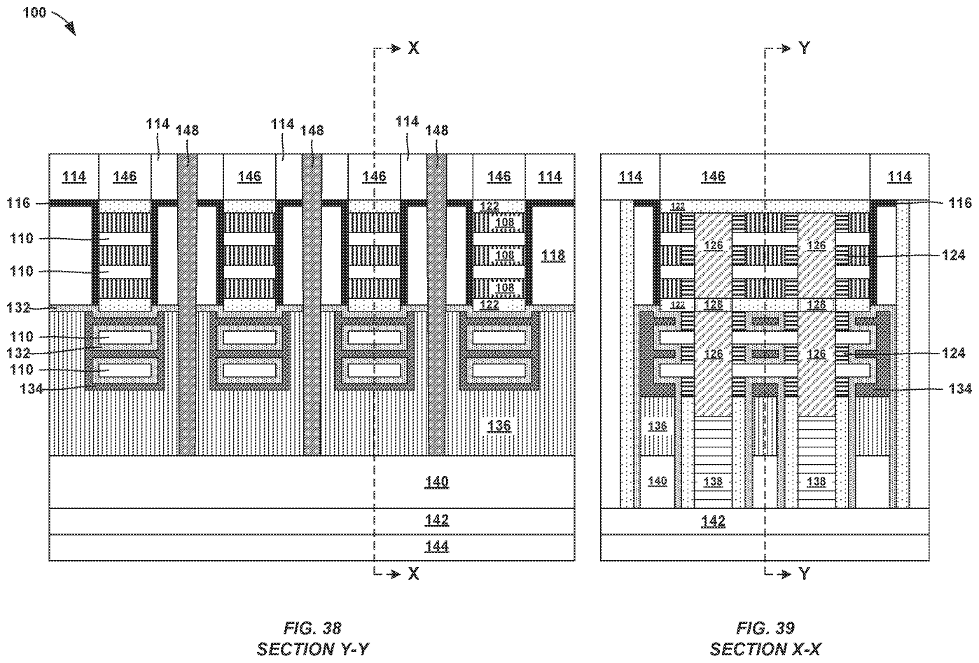

Referring now to FIGS. 38 and 39, a structure 100 is shown after forming dielectric pillars 148 to isolate adjacent devices according to an embodiment of the invention. FIG. 38 depicts a cross-sectional view of the structure 100 shown in FIG. 39 taken along line X-X, and FIG. 39 depicts a cross-sectional view of the structure 100 shown in FIG. 38 taken along line Y-Y.

A gate cut mask is applied, trenches are formed, and the trenches are filled with a dielectric material to form the dielectric pillars 148 between adjacent devices according to known techniques. The dielectric pillars 148 extend through or past all active elements (110, 132, 134) all the way to the self-aligned cap 140. Doing so ensures cuts or separates the metal gate structures between adjacent devices. In general, the metal gate structures will be cut or separate by some dielectric structure based on design. Here, for example, a dielectric pillar is shown and described between each nanosheet stack 106; however, such is not required.

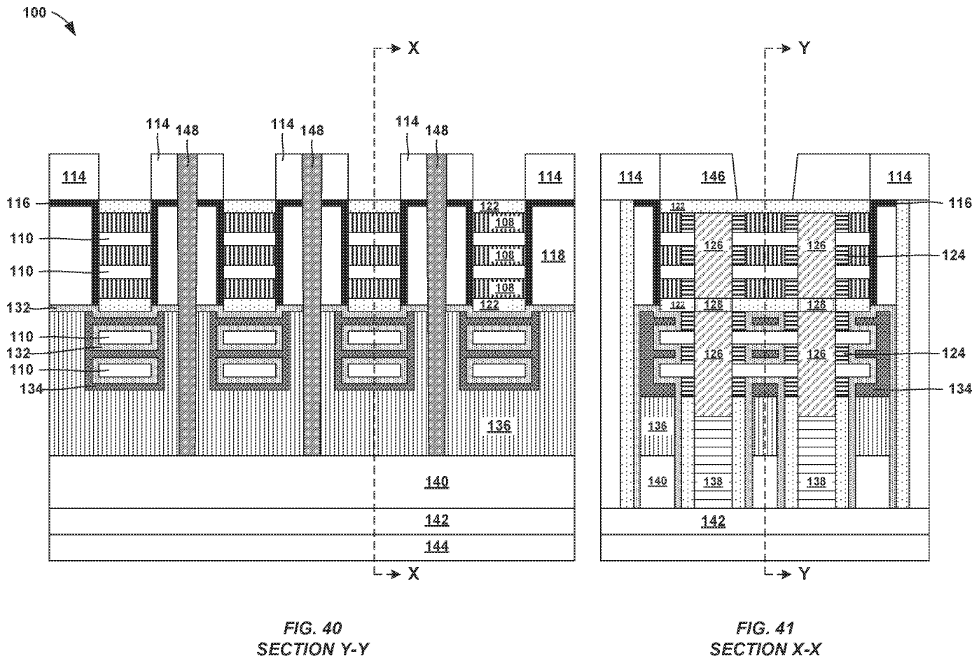

Referring now to FIGS. 40 and 41, a structure 100 is shown after removing portions of the dielectric fill 146 in preparation for forming gate structures in the bottom devices according to an embodiment of the invention. FIG. 40 depicts a cross-sectional view of the structure 100 shown in FIG. 41 taken along line X-X, and FIG. 41 depicts a cross-sectional view of the structure 100 shown in FIG. 40 taken along line Y-Y.

Due to the flipped orientation, the bottom devices are depicted above the top devices; however, the relative terms “upper”, “lower”, “right”, “left”, “vertical”, “horizontal”, “top”, “bottom”, and derivatives thereof shall continue relate to the disclosed structures and methods, as oriented in the drawing figures. The portions of the dielectric fill 146 in gate regions are patterned and etched to expose the spacer material 122 according to known techniques, as illustrated in FIG. 41.

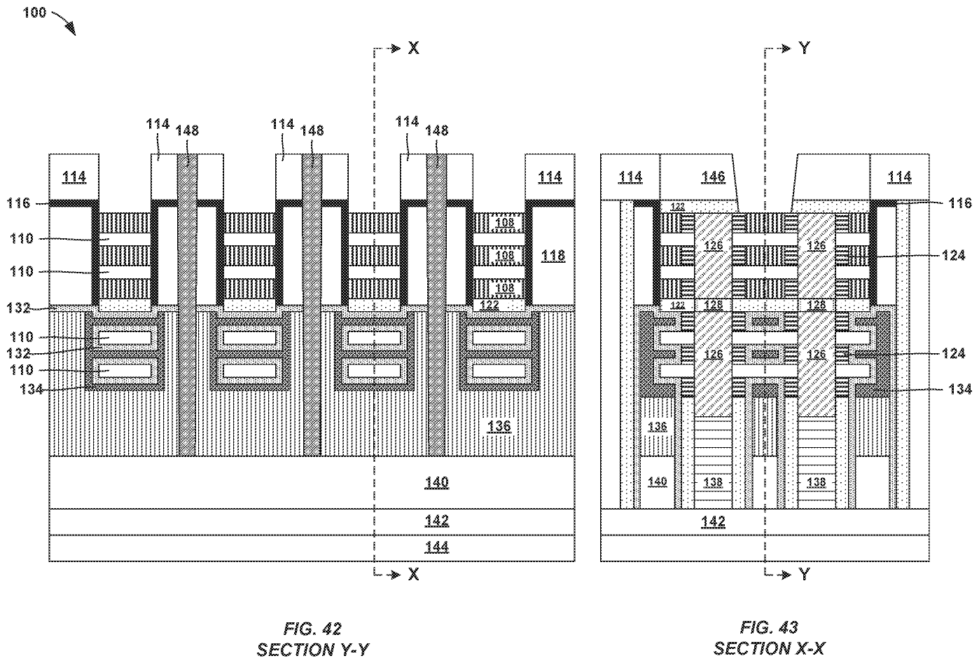

Referring now to FIGS. 42 and 43, a structure 100 is shown after etching exposed portions of the spacer material 122 according to an embodiment of the invention. FIG. 42 depicts a cross-sectional view of the structure 100 shown in FIG. 43 taken along line X-X, and FIG. 43 depicts a cross-sectional view of the structure 100 shown in FIG. 42 taken along line Y-Y.

In doing so, exposed portions of the spacer material 122 are etched or removed until the first sacrificial nanosheets 108 are exposed. In some embodiments, the same mask maybe used to pattern and etch both the dielectric fill 146 and the spacer material 122.

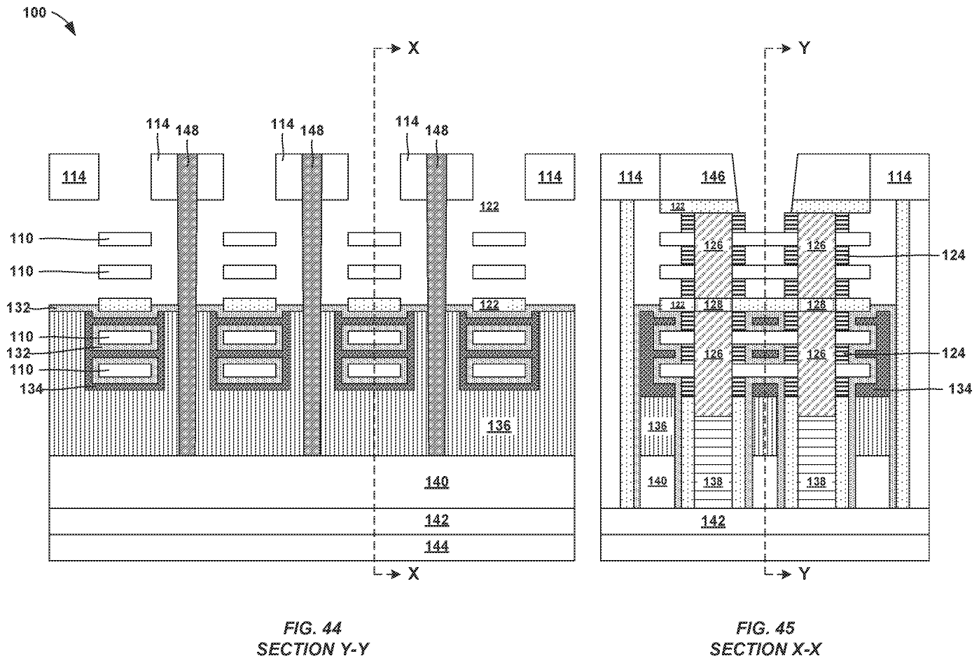

Referring now to FIGS. 44 and 45, a structure 100 is shown after selectively removing the first sacrificial nanosheets 108, the sacrificial gate dielectric 116, and the first sacrificial gate 118 according to an embodiment of the invention. FIG. 44 depicts a cross-sectional view of the structure 100 shown in FIG. 45 taken along line X-X, and FIG. 45 depicts a cross-sectional view of the structure 100 shown in FIG. 44 taken along line Y-Y.

First, topmost portions of the sacrificial gate dielectric 116 are removed to expose the first sacrificial gate 118. After, the first sacrificial gate 118 is etched and removed selective to the first gate dielectric 132, the channel nanosheets 110, the STI regions 114, the dielectric pillars 148, the first sacrificial nanosheets 108, and the spacer material 122 according to known techniques. Remaining vertical portions of the sacrificial gate dielectric 116 are removed are then etched and removed selective to the nanosheet stacks 106.

Next, the first sacrificial nanosheets 108 are etched and removed selective to the channel nanosheets 110, the sacrificial gate dielectric 116, and the spacer material 122 according to known techniques. Doing so is made possible by the different concentrations of germanium. In this case, the layers with germanium are removed selective to layers without germanium. Here, it is noted the remaining first sacrificial nanosheets 108 are removed from the bottom devices.

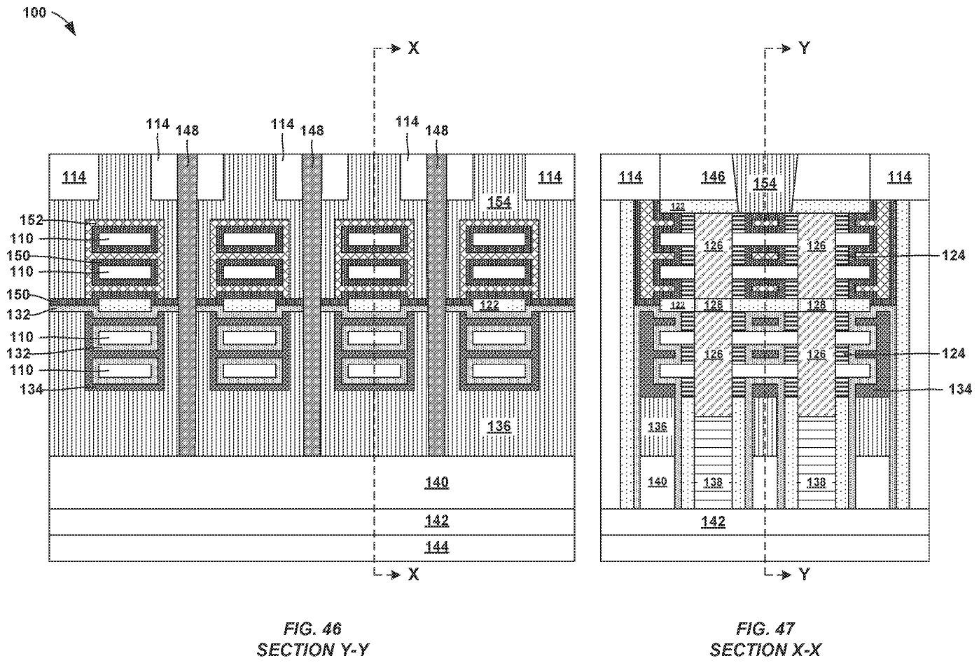

Referring now to FIGS. 46 and 47, a structure 100 is shown after forming a bottom gate structure including a second gate dielectric 150, a second work function metal layer 152, and a second gate metal 154 according to an embodiment of the invention. FIG. 46 depicts a cross-sectional view of the structure 100 shown in FIG. 47 taken along line X-X, and FIG. 47 depicts a cross-sectional view of the structure 100 shown in FIG. 46 taken along line Y-Y.

First, the second gate dielectric 150 is conformally deposited directly on exposed surfaces of the structure 100 within the openings and spaces left by removing the first sacrificial gate 118 and the first sacrificial nanosheets 108 according to known techniques. For example, the second gate dielectric 150 is conformally deposited on exposed surfaces of the channel nanosheets 110 and the inner spacers 124, as best illustrated in FIG. 47. Additionally, the second gate dielectric 150 is conformally deposited on exposed surfaces of the spacer material 122, as best illustrated in FIG. 46. Although not shown, the second gate dielectric 150 will also be deposited on vertical sidewalls of the dielectric pillars 148.

The second gate dielectric 150 is composed of any known gate dielectric materials, for example, oxide, nitride, and/or oxynitride. In an example, the second gate dielectric 150 can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNx, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the second gate dielectric 150. According to an embodiment of the present invention, the second gate dielectric 150 is a different material or composition from the first gate dielectric 132. This is made possible by the spacer material 122 separating top devices from bottom devices. In another embodiment, the second gate dielectric 150 is the same material or composition as the first gate dielectric 132.

Next, the second work function metal layer 152 is conformally deposited on the second gate dielectric 150 formed within the gate cavities of the bottom devices according to known techniques. In at least one embodiment, the second work function metal layer 152 is made of the same conductive material across the entire structure. In at least another embodiment, the second work function metal layer 152 is made from different conductive materials in each of the four devices illustrated in FIG. 42. In doing so, the different conductive materials would be deposited successively according to the design parameters and desired operation characteristics.

The second work function metal layer 152 can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium cabon (TiC), titanium aluminum (TiAl), titanium aluminum carbon (TiAlC), or multilayered combinations thereof. In some embodiments, the second work function metal layer 152 can include an nFET gate metal. In other embodiments, the second work function metal layer 152 can include a pFET gate metal. When multiple gate cavities are formed, as illustrated herein, embodiments of the present invention explicitly contemplate forming an nFET in at least one of the gate cavities and a pFET in at least another one of the gate cavities. Additionally, according to an embodiment of the present invention, the second work function metal layer 152 is a different material or composition from the first work function metal layer 134. This is made possible by the spacer material 122 separating top devices from bottom devices. In another embodiment, the second work function metal layer 152 is the same material or composition as the first work function metal layer 134.

Finally, the second gate metal 154, or contact metal, is deposited directly on the second work function metal layer 152 and fills the gate cavities. The second gate metal 154 may include any suitable conductive material, such as, for example, copper, ruthenium, aluminum, tungsten, cobalt, or alloys thereof. After, excess conductive material can be polished using known techniques until a topmost surface of the second gate metal 154 is flush, or substantially flush, with topmost surfaces of the bottom dielectric layer 130. Additionally, according to an embodiment of the present invention, the second gate metal 154 is a different material or composition from the first gate metal 136. This is made possible by the spacer material 122 separating top devices from bottom devices. In another embodiment, the second gate metal 154 is the same material or composition as the first gate metal 136.

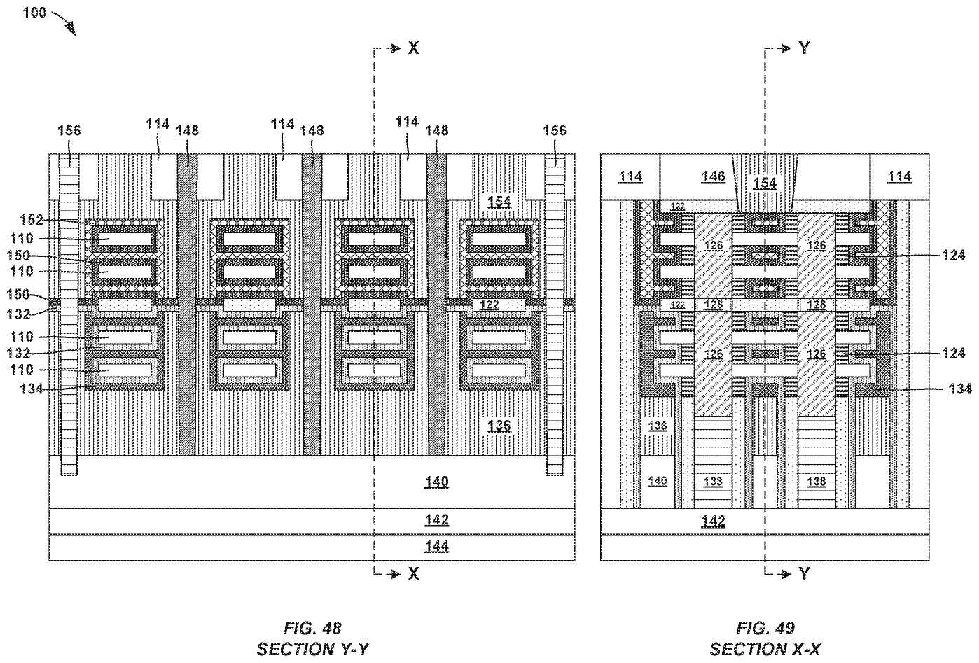

Referring now to FIGS. 48 and 49, a structure 100 is shown after forming gate contact structures 156, or CB contacts, according to an embodiment of the invention. FIG. 48 depicts a cross-sectional view of the structure 100 shown in FIG. 49 taken along line X-X, and FIG. 49 depicts a cross-sectional view of the structure 100 shown in FIG. 48 taken along line Y-Y.

First, contact trenches are formed and then filled with a conductive material to form the contact structures 156 according to known techniques. The contact structures 156 of the present embodiment are designed to merge the gate structure of a top device with the gate structure of a bottom device, as illustrated. Therefore, so long as the contact structures 156 contact the second gate metal 154 of a bottom device and the first gate metal 136 of a top device, as illustrated, they will form the desired electrical connection. Subsequently, additional electrical connections to or from the contact structures 156 can be made from either the front side of the structure 100, the back side of the structure 100, or both. According to an alternative embodiment not shown, the gate structures of the top and bottom devices remain isolated from one another, and separate gate contacts are formed.

The contact structures 156 may include any suitable conductive material, such as, for example, copper, ruthenium, aluminum, tungsten, cobalt, or alloys thereof. After, excess conductive material can be polished using known techniques. In other cases, the contact structures 156 may be subsequently recessed and back filled with a dielectric depending on the design requirements.

FIGS. 48 and 49, the stacked transistor structures represented by the structure 100 has some distinctive notable features. For purposes of this description the structure 100 illustrated in the figures and described herein includes an array of four stacked transistor structures positioned adjacent, or next, to one another, and manufactured in a single replacement gate process flow. Further, each of the stacked transistor structures includes a top device and a bottom device. More specifically, all top devices and all bottom devices have a nanosheet or gate-all-around structure.

In sum, the structure 100 and associated process flow enable manufacturing of stacked devices having multiple threshold voltages. Even more specifically, the threshold voltage of each individual device of the structure 100 can be fine-tuned or adjusted separately form one another. This is accomplished by using a bilayer gate dielectric layer which separates individual top devices from individual bottom devices. The bilayer gate dielectric layer is made from the first gate dielectric 132 and the second gate dielectric 150. With the existence of the bilayer gate dielectric layer, top devices are automatically electrically isolated from bottom devices without the need for additional isolation structures. It is noted, the dielectric spacer 122 initially prepared to provide some dielectric isolation between top and bottom devices; however, in practice the dielectric spacer 122 will not isolate subsequently formed gate structures. In the present embodiment, the dielectric spacer 122 is sandwiched between two layers of the bilayer gate dielectric layer. Although, the bilayer gate dielectric layer can have two layers of the same material, the advantages of the present invention are fully realized when the bilayer gate dielectric layer includes two layers of different gate dielectric materials. Further, the bilayer gate dielectric layer separates, or electrically insulates, the top gate structure of the top device from the bottom gate structure of the bottom device. Because of the bilayer gate dielectric layer, each individual device, top or bottom, can be fabricated with different materials and thus have different properties. Specifically, the structures and method described herein enable fabricating each individual device with different gate dielectric materials and different work function materials. For example, each of the four top devices may be fabricated with different combinations of gate dielectric and work function metals, and the same for the bottom devices. As such, the threshold voltage and properties for each device is individually tunable.

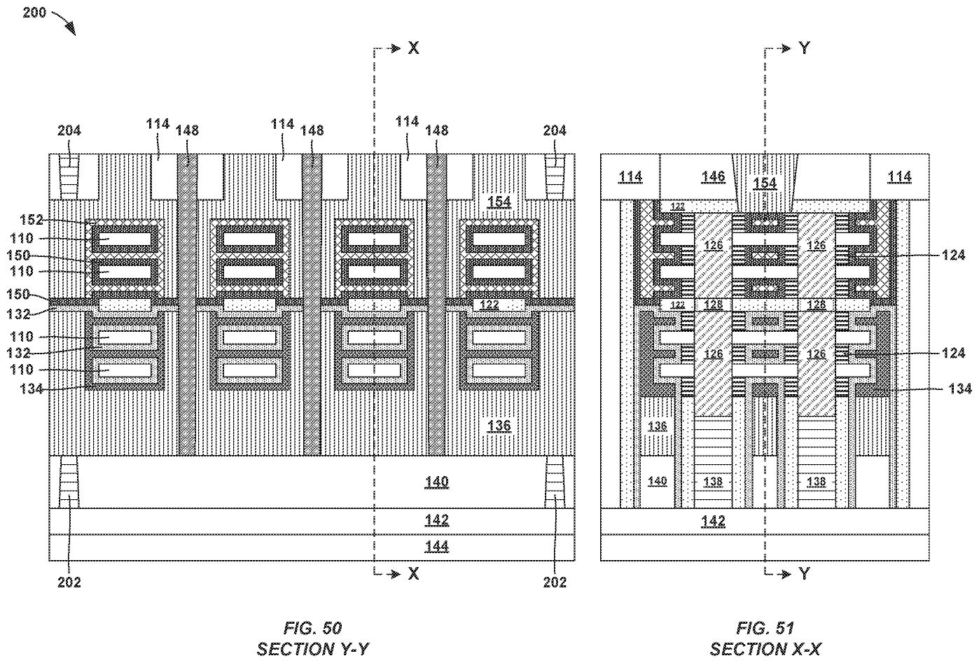

Referring now to FIGS. 50 and 51, a structure 200 is shown during an intermediate step of a method of fabricating a stacked transistor structure according to an alternative embodiment of the invention. Specifically, the structure 200 is nearly identical to the structure 100 described above; however, with a different gate contact configuration. Specifically, the structure 200 has first gate contacts 202 and second gate contacts 204. Unlike the gate contacts 156 of the structure 100, the first gate contacts 202 and the second gate contacts 204 form separate connections to the first gate metal 136 and the second gate metal 154, respectively. Alternatively, the first gate contacts 202 may be referred to as a front-side gate contact and connect to the MOL/BEOL 142. Meanwhile, the second gate contacts 204 may be referred to as a back-side gate contact and connect to backside wiring.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a stacked transistor structure comprising a top device stacked directly above a bottom device; and
a bilayer gate dielectric layer separating the top device from the bottom device.

2. The semiconductor structure according to claim 1, further comprising:
a dielectric spacer sandwiched between two layers of the bilayer gate dielectric layer, wherein a width of the dielectric spacer is equal to a width of a channel nanosheet of the top device and a channel nanosheet of the bottom device.

3. The semiconductor structure according to claim 1, further comprising:
a spacer material separating a top source drain region of the top device from a bottom source drain region of the bottom device.

4. The semiconductor structure according to claim 1, wherein the bilayer gate dielectric layer comprises two different gate dielectric layers.

5. The semiconductor structure according to claim 1, wherein the bilayer gate dielectric layer separates a top gate structure of the top device from a bottom gate structure of the bottom device.

6. The semiconductor structure according to claim 1, further comprising:
a gate contact extending through the bilayer gate layer dielectric layer and electrically connecting a top gate structure of the top device from a bottom gate structure of the bottom device.

7. The semiconductor structure according to claim 1,
wherein the top device and the bottom device each comprise different work function metals.

8. A semiconductor structure comprising:
a first stacked transistor structure comprising a top device stacked directly above a bottom device;
a second stacked transistor structure adjacent to the first stacked transistor, the second stacked transistor comprising a top device stacked directly above a bottom device; and
a bilayer gate dielectric layer separating the top devices from the bottom devices.

9. The semiconductor structure according to claim 8, further comprising:
a dielectric spacer sandwiched between two layers of the bilayer gate dielectric layer, wherein a width of the dielectric spacer is equal to a width of a channel nanosheet of the top device and a channel nanosheet of the bottom device.

10. The semiconductor structure according to claim 9, further comprising:
a spacer material separating a top source drain regions of the top devices from bottom source drain regions of the bottom devices.

11. The semiconductor structure according to claim 8, wherein the bilayer gate dielectric layer comprises two different gate dielectric layers.

12. The semiconductor structure according to claim 8, wherein the bilayer gate dielectric layer separates a top gate structure of the top device from a bottom gate structure of the bottom device.

13. The semiconductor structure according to claim 8, further comprising:
a gate contact extending through the bilayer gate dielectric layer and electrically connecting a top gate structure of the top device from a bottom gate structure of the bottom device.

14. The semiconductor structure according to claim 8,
wherein the top device of the first stacked transistor structure, the top device of the second stacked transistor structure, the bottom device of the first stacked transistor structure, and the bottom device of the second stacked transistor structure each comprise different work function metals.

15. A semiconductor structure comprising:
a stacked nanosheet transistor array comprising a plurality of top devices stacked directly above a plurality of bottom devices, wherein each of the plurality of top devices comprises a different threshold voltage, wherein each of the plurality of bottom devices comprises a different threshold voltage; and
a bilayer gate dielectric layer separating each of the plurality of top devices from each of the plurality of bottom devices.

16. The semiconductor structure according to claim 15, further comprising:
a dielectric spacer sandwiched between two layers of the bilayer gate dielectric layer, wherein a width of the dielectric spacer is equal to a width of channel nanosheets of the top devices and channel nanosheets of the bottom devices.

17. The semiconductor structure according to claim 16, further comprising:
a spacer material separating top source drain regions of the top devices from a bottom source drain regions of the bottom devices.

18. The semiconductor structure according to claim 15, wherein the bilayer gate dielectric layer comprises two different gate dielectric layers.

19. The semiconductor structure according to claim 15, wherein the bilayer gate dielectric layer separates top gate structures of the top devices from bottom gate structures of the bottom devices.

20. The semiconductor structure according to claim 15, further comprising:
a gate contact extending through the bilayer gate dielectric layer and electrically connecting at least one top gate structure of at least one top device from at least one bottom gate structure of at least one bottom device.
